(19) United States
(12) Patent Application Publication
(10) Pub. No.: US 2023/0230852 A1
(43) Pub. Date: Jul. 20, 2023

(54) COLD PLATE MADE VIA 3D PRINTING

(71) Applicant: 3M INNOVATIVE PROPERTIES COMPANY, St. Paul, MN (US)

(72) Inventors: Elizaveta Y. Plotnikov, Woodbury, MN (US); Sung W. Moon, Woodbury, MN (US); Nicholas A. Proite, St. Paul, MN (US); Myron K. Jordan, Apple Valley, MN (US)

(21) Appl. No.: 18/011,263

(22) PCT Filed: Jul. 9, 2021
(86) PCT No.: PCT/IB2021/056185

§ 371 Date: Dec. 19, 2022

Related U.S. Application Data
(60) Provisional application No. 63/049,745, filed on Jul. 9, 2020.

(51) Int. Cl. H01L 21/48; H01L 23/473

(52) U.S. Cl. CPC H01L 21/4882; H01L 23/473; B33Y 80/00

(57) ABSTRACT

A cold plate having a copper base plate and a plurality of fins on the copper base plate. The fins are porous and made by 3D printing a copper-silver alloy on the copper base plate. Alternatively, the fins can be 3D printed and then adhered to the copper base plate with a brazing material. The copper base plate is placed on electronics to be cooled, such as a chip package, using a thermal interface material. An optional manifold can be placed on the copper base plate for circulating a coolant across the fins.

### BACKGROUND

Cold plates offer an efficient way for processors to be cooled during operation, which can extend the lifetime of high-value integrated circuit chips. Processors such as those used in server racks located in large data centers can produce 600 W of heat during operation. Given the close spacing of processors in a server rack, as well as spacing between server racks, air cooling is not an efficient solution at scale, especially as the industry moves to more artificial intelligence and machine learning capability, which requires more processing power than other uses. Traditional direct-to-chip cooling plates consist of a copper plate with straight thin fins machined into the surface using, for example, a CNC or skiving machine. Such a structure can generally achieve a thermal resistivity of approximately 0.05° C./W at a flow rate of 1 L/min.

### SUMMARY

A cold plate includes a metal base plate and a plurality of fins on the metal base plate. The fins are porous and comprise an additively manufacturable material.

A cold plate cooling system includes a metal plate, a cold plate on the metal plate, and a manifold on the metal plate and over the cold plate. The manifold includes at least one first port for receiving a coolant into the manifold and at least one second port for exiting the coolant from the manifold. The cold plate includes a metal base plate and a plurality of fins or pins on the metal base plate, where the fins or pins are porous and comprise an additively manufacturable material.

A first method for making a cold plate includes providing a metal base plate and 3D printing a plurality of porous fins or pins on the metal base plate.

A second method for making a cold plate includes providing a metal base plate, 3D printing a plurality of porous fins or pins, and adhering the fins or pins to the metal base plate.

### BRIEF DESCRIPTION OF THE DRAWINGS

FIG. 1A is a perspective diagram of a cold plate cooling system.

FIG. 1B is a perspective diagram of a cold plate.

FIG. 1C is a diagram of a system for additive manufacturing of an article.

FIG. 1D is a flow chart of a method for additive manufacturing of an article.

FIG. 2 are images showing: a.) positioning of copper plate into the build side of the printer using a 3D printed adaptor, b.) filling of supply side of printer with powder, c.) spreading first layer of powder to cover the copper plate, and d.) finished finned structure after printing.

FIG. 3 are images showing: printed finned structure on the machined Copper Plate before and after the heat treatment used to evaporate the water in the ExOne Aqueous Binder.

FIG. 4 are images showing: Machined Copper Plate with printed finned structure before and after the sintering heat treatment.

FIG. 5 are images showing: Standalone finned structure before and after secondary heat treatment.

FIG. 6 are images showing: Machined Copper Plates with braze foil and paste applied to designated area for brazing.

FIG. 7 are images showing: Plate/braze/printed structure assembly after being brazed to the Copper plates using (left) brazing foil and (right) brazing paste.

FIG. 8 is a schematic of custom benchtop testing apparatus.

FIG. 9 is a graph comparing simulated performance with experimentally determined values of thermal resistance for the three samples.

FIG. 10 is a backscatter image for the finned structure made for EXAMPLE 2, showing horizontal lines indicating the presence of layers and a porous structure from 3D printing.

FIG. 11 is a backscatter image for the finned structure made for EXAMPLE 2, showing horizontal lines indicating the presence of layers and a porous structure from 3D printing.

### DETAILED DESCRIPTION

Embodiments of the present invention include a method to create a finned structure on a copper plate using 3D printing via binder jetting. This 3D printed metal structure comprises, for example, straight or curved fins of copper or a copper-silver alloy to be used for single phase direct-to-chip cooling for electronic applications. Binder jetting offers several advantages over traditional milling including potentially higher throughput during manufacturing and a final structure that is porous and has a high surface roughness, thus increasing the total surface area in contact with the cooling fluid.

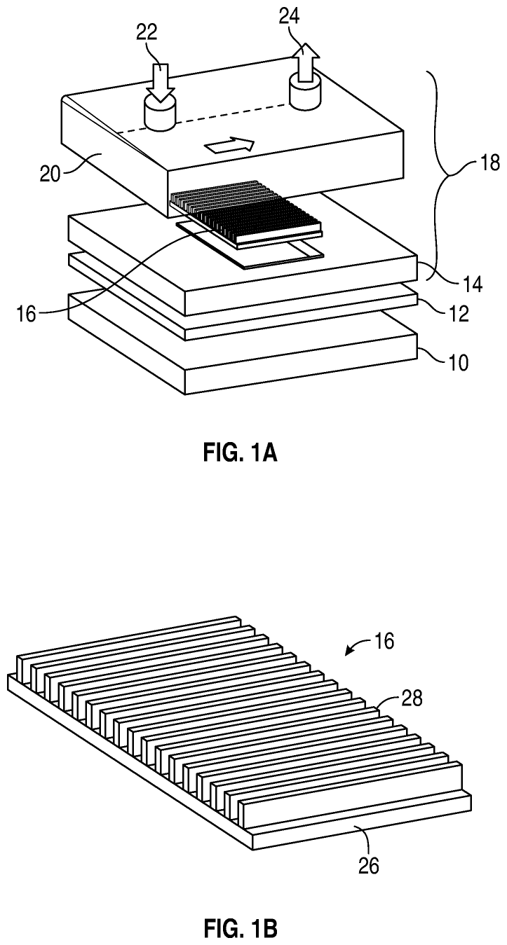

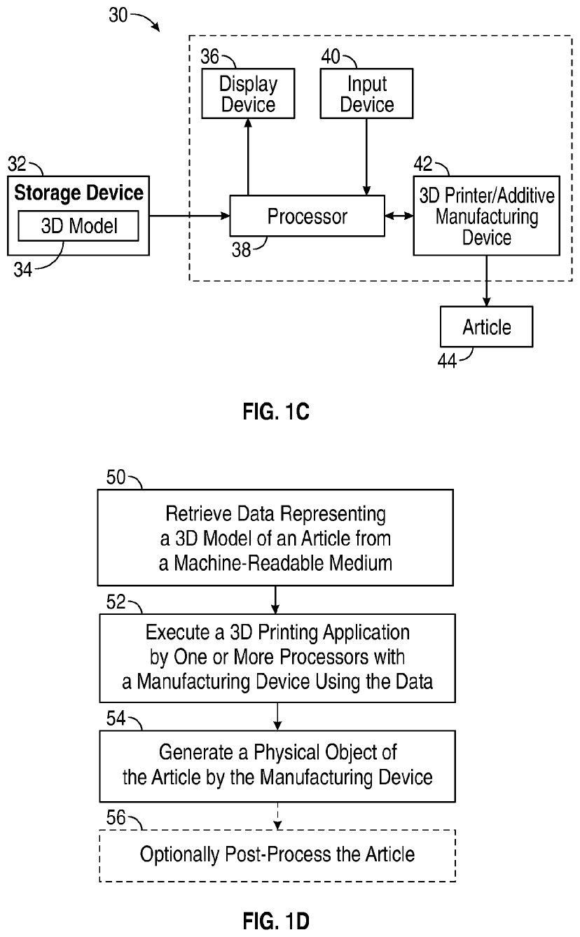

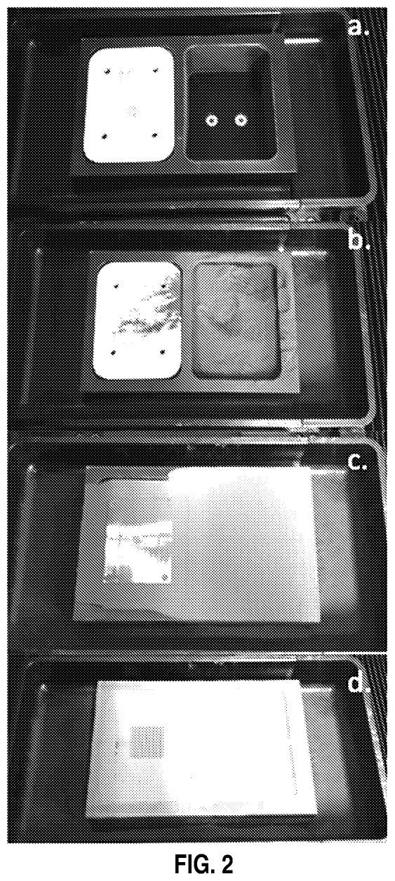

FIG. 1A is a perspective diagram of a cold plate cooling system for cooling electronics such as a chip package 10 having thermal interface material 12. The cooling system includes a copper plate 14 in physical contact with thermal interface material 12, a heat sink 16 on and in physical contact with copper plate 14, and an optional manifold 20 over heat sink 16 and in physical contact with copper plate 14. Manifold 20 includes at least one port 22 for receiving a coolant to flow across heat sink 16 and at least one port 24 for the coolant to exit manifold 20. Copper plate 14, heat sink 16, and manifold 20 form a thermomodule 18 for cooling chip package 10.

FIG. 1B is a perspective diagram of heat sink 16, which forms a cold plate. Heat sink 16 include a metal base plate 26 and fins 28 formed on metal base plate 26. Alternatively, fins 28 can be formed without base plate 26 for placement directly on copper plate 14 by adhering them to copper plate 14 with, for example, a brazing material. Fins 28 comprise a porous structure made via 3D printing using an additively manufacturable material, as described in the Examples. Since the fins are 3D printed, they can include a cross-sectional signature by the presence of layers, indicating the fins were made via 3D printing such as binder jetting. The fins include pores typically 5 microns-10 microns in diameter. Exemplary sizes for the fins include a 600 micron width of the fins and a 500 micron spacing of the fins (channel width). A typical range of features sizes for the fins, or other structures for a cold plate, is 300 microns to 1 mm. These exemplary sizes are as printed, since the features will shrink 20%-25% after heat treatment. The fins can be curved or straight, and can be continuous or discontinuous. If the fins are discontinuous, they can resemble pins.

In some embodiments, a non-transitory machine-readable medium is used in additive manufacturing of cold plates according to at least some embodiments. Data is typically stored on the machine-readable medium. The data represents a three-dimensional model of a cold plate or a series of two dimensional models, which when layered on top of one another comprise a three-dimensional model, which can be accessed by at least one computer processor interfacing with additive manufacturing equipment (e.g., a 3D printer, a manufacturing device, or other such devices). The data is used to cause the additive manufacturing equipment to create the cold plate. As used herein, the term “three-dimensional model” refers to both one model having three dimensions and two or more models each having two dimensions, which stacked on top of each other provide a three-dimensional model.

Data representing a cold plate can be generated using computer modeling, such as computer aided design (CAD) data. Image data representing the cold plate design can be exported in STL format, or in any other suitable computer processable format, to the additive manufacturing equipment. Scanning methods to scan a three-dimensional object may also be used to create the data representing the cold plate. One exemplary technique for acquiring the data is digital scanning Any other suitable scanning technique can be used for scanning an article, including X-ray radiography, laser scanning, computed tomography (CT), magnetic resonance imaging (MRI), and ultrasound imaging. Other possible scanning methods are described, for example, in U.S. Patent Application Publication No. 2007/0031791. The initial digital data set, which may include both raw data from scanning operations and data representing articles derived from the raw data, can be processed to segment a cold plate design from any surrounding structures (e.g., a support for the cold plate).

Machine-readable media can be provided as part of a computing device. The computing device may have one or more processors, volatile memory (RAM), a device for reading machine-readable media, and input/output devices, such as a display, a keyboard, and a pointing device. Further, a computing device may also include other software, firmware, or combinations thereof, such as an operating system and other application software. A computing device can be, for example, a workstation, a laptop, a personal digital assistant (PDA), a server, a mainframe or any other general-purpose or application-specific computing device. A computing device may read executable software instructions from a computer-readable medium such as a hard drive, a CD-ROM, or a computer memory, or may receive instructions from another source logically connected to computer, such as another networked computer.

FIG. 1C is a diagram of a system 30 for additively manufacturing an article. The system 30 includes a display devices 36 that can display a 3D model 34 of an article (e.g., a cold plate as shown in FIG. 1B), and one or more processors 38 that, in response to the 3D model 34 selected by a user or otherwise activated, cause a 3D printer/additive manufacturing device 42 to create a physical object of the article 44. An input device 40 (e.g., keyboard and/or cursor control device) can be used with the display device 36 and the at least one processor 38, particularly for the user to select the 3D model 34. The 3D model 34 is typically stored within a storage device 32 such as a non-transitory machine-readable memory, accessed by processor 38 locally or remotely via a network. The cold plate 44 comprises a metal base plate and a plurality of porous fins on the metal base plate. The cold plate comprises a number of layers of metal directly bonded to each other.

FIG. 1D is a flow chart of an additive manufacturing method. This method can be implemented and executed at least in part by, for example, system 30. The method includes retrieving 50 from a non-transitory machine-readable medium, data representing a 3D model of an article according to at least one embodiment (i.e., a cold plate). The method further includes executing 52 by one or more processors (e.g., processor 38) an additive manufacturing application via a manufacturing device (e.g., device 42) using the data such as a 3D model, and generating 54 by the manufacturing device a physical object of the article such as a desired cold plate. One or more various optional post-processing steps 56 can be undertaken, for instance and without limitation, support removal and heat treatment.

EXAMPLES

| Abbreviation | Description and Source |
|---|---|
| 101 Copper | Super-Conductive 101 Copper Sheet; ⅛ Hard Temper, 12″ × 48″, ⅛″ |
| | Thick McMaster-Carr, catalog number 89675K56 |
| Copper Powder | CHEM COPP 1700, American Chemet Corporation, Deerfield, IL |
| Silver | Custom 99.99% pure silver target. Dimensions were 0.5 × 0.5 × 12″ |
| | ordered from Academy Group (Albuquerque, NM) - company is now part |
| | of Materion |
| Aqueous Binder | Product ID: BA005, item numbers: 70 100037CL, 7110015 (per |
| | manufacturer's SDS contents are water, ethynediol, 2-butoxyethanol, and |
| | unnamed trade secret contents) from ExOne, North Huntingdon, PA |
| | SILVER BRAZE 45 (AWS BAg-5 compliant), Prince & Izant, Cleveland, |
| | OH |

### Example 1: Printing of Finned Structure Directly onto Copper Plate

A flat plate of 101 Copper 12″×48″, ⅛″ was machined to 45×34×3 mm. Mounting holes were drilled at the four corners and a thermocouple slot was milled into one side. A flatness requirement was specifically called out to the extent needed or desired to compensate for warpage of the plate during machining.

Copper Powder (D90<20 μm) was plasma coated with silver as described in U.S. Pat. No. 7,727,931, col. 13 line 40—col. 14 line 39 with the gold target replaced with silver, to create a thin (˜20 nm) nonuniform coating to produce copper-silver powder. The powder was loaded into an Mlab binder jet 3D printer from ExOne (North Huntingdon, Pa.), and the printer was prepared for printing following a standard manufacturer recommended startup process. The printer used ExOne's Aqueous Binder.

The machined Copper Plate was inserted into a 3D printed adaptor in order to fit snuggly into the 50×70 mm build side of the printer and to make sure the finned structure would be centered on the plate. A CAD file containing a set of fins that were 1 mm thick and 0.6 mm tall was loaded into the printer software. Printing was carried out using the parameters listed in Table 1. The first layer was printed directly onto the copper plate, with each subsequent layer thus being adhered to the plate as well. The preparation and printing process is shown in FIG. 2.

TABLE 1
Printing parameters used for producing the finned structures.
Note that the drying power control setting is much lower
than ExOne recommends using for their standard powders.

| Print parameter | Value |
|---|---|
| Layer thickness | 65 μm |
| Powder packing rate | 60% |
| Desired saturation | 100% |
| Drying time (per layer) | 60 sec |
| Spreader speed | 5 mm/sec |
| Drying power control setting | 50% |
| Foundation layers | 0 |
| Feed powder to layer thickness ratio | 1.80 |

Following the printing step, the copper plate was carefully lifted out of the printer without disturbing either the printed finned structure or the powder surrounding it, and heat treated to remove the majority of the water content in the aqueous binder.

The heat treatment took place in a hydrogen atmosphere 1200 series furnace from CM furnaces. The following heat treatment cycle was used:

1. 20 minutes purge at room temperature with 100% nitrogen at a flow rate of 80 SCFH.

2. Gas switched to 100% hydrogen at a flow rate of 10 SCFH.

3. Heat to 195° C. at a rate of 5° C./min.

4. Hold at 195° C. for 2 hours.

5. Cool to 80° C. at a rate of 5° C./min (see below).

6. Gas switched to 100% nitrogen at a flow rate of 80 SCFH.

7. Purge with nitrogen for 20 minutes.

While a nominal cooling rate of 5° C./min was programmed into the furnace, the furnace did not have the means to cool itself down that quickly. The program instead allowed the furnace to cool as quickly as possible, with a 10° C. holdback from the programmed rate.

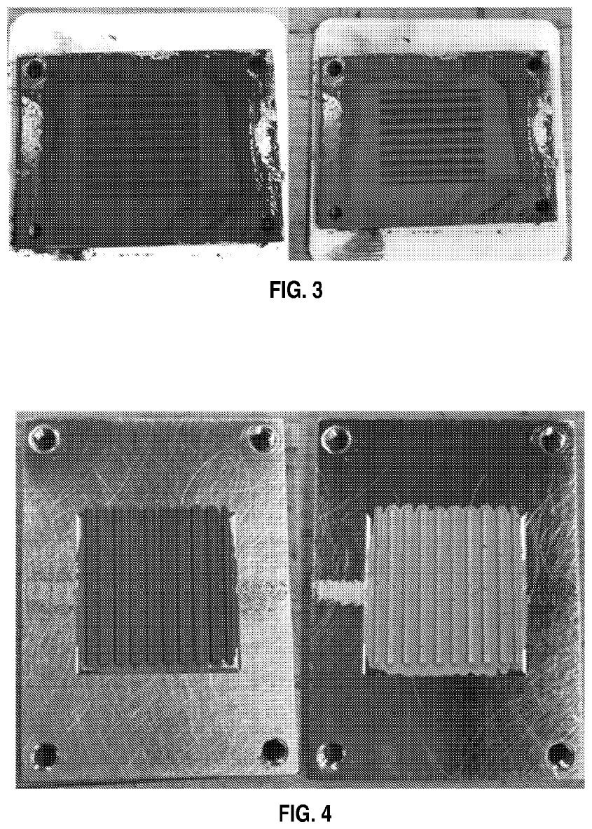

FIG. 3 shows the printed finned structure on the machined Copper Plate before and after the heat treatment process. The slight change in color was indicative of the effect of the reducing atmosphere of the furnace on the copper content of the metal powder.

Following the heat treatment process, the loose powder was manually brushed off the machined Copper Plate, leaving behind just the printed structure. Small remaining amounts of loose powder were blown off with a low-pressure air hose.

The cleaned “green” part was then subjected to a second heat treatment (in the same furnace) to sinter the structure together. The following heat treatment cycle was used:

1. 20 minutes purge at room temperature with 100% nitrogen at a flow rate of 80 SCFH.

2. Gas switched to 100% hydrogen at a flow rate of 10 SCFH.

3. Heat to 500° C. at a rate of 5° C./min.

4. Hold at 500° C. for 1 hour.

5. Heat to 900° C. at a rate of 5° C./min.

6. Hold at 900° C. for 10 hours.

7. Cool to 100° C. at a rate of 5° C./min (see below).

8. Gas switched to 100% nitrogen at a flow rate of 80 SCFH.

9. Purge with nitrogen for 20 minutes.

While a nominal cooling rate of 5° C./min was programmed into the furnace, the furnace did not have the means to cool itself down that quickly. The program instead allowed the furnace to cool as quickly as possible, with a 10° C. holdback from the programmed rate.

FIG. 4 shows the machined Copper Plate and printed finned structure before and after the sintering heat treatment. The change in color was indicative of the reducing atmosphere of the furnace. The fins were visually thinner after the sintering process due to the consolidation and densification of the powder. The empirically observed linear shrinkage in the x-y plane of this powder was 22%, with the top (not constrained) of the printed part shrinking slightly more than the bottom (constrained). Therefore, while the fins were printed to a nominal width of 1 mm, the resulting width after sintering was ˜800 μm.

### Example 2: Printing then Brazing of a Stand-Alone Finned Structure

Stand-alone finned structures with a base were printed using the same printing parameters outlined in EXAMPLE 1.

Instead of using a copper plate as the base for the first layer, the printed parts were suspended in loose powder during and after the print. The printed structures consisted of straight fins and a square base 1 mm thick. The printed structures were oversized 27% in the x-y plane in order to compensate for shrinkage during sintering.

The parts were printed and heat treated using the parameters described in EXAMPLE 1, with one exception: the hold time at 900° C. during the second heat treatment was reduced from 10 hours to 4 hours.

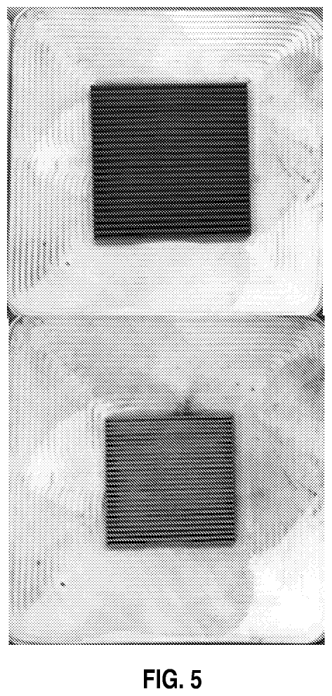

FIG. 5 shows one finned structure before and after the second (higher temperature) heat treatment. Note the shrinkage of the structure following the heat treatment (photos are the same scale). The overall shrinkage was more dramatic than in FIG. 4 because the standalone finned structure was not on a copper plate that would act as an anchor for the bottom surface of the printed structure. Therefore, it was able to shrink much more than EXAMPLE 1.

Following the second heat treatment process, the finned structures were brazed onto clean copper plates (machined according to EXAMPLE 1). Silverbraze 45 brazing material was used in two different forms: 1) thin foil; 2) paste/slurry.

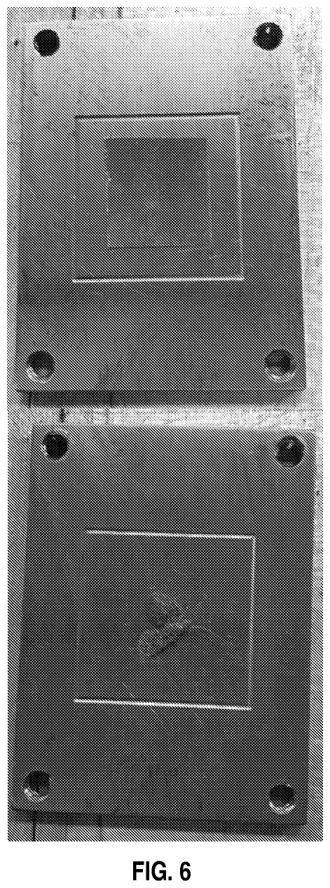

The braze materials were applied to the machined Copper Plates (FIG. 6) and the printed finned structures were laid on top of the braze material.

FIG. 6 are images showing: Machined Copper Plates with braze foil and paste applied to designated area for brazing.

The stack of machined Copper Plate, braze material, and printed finned structure were heat treated to form a plate/braze/printed structure assembly according to the following program (same furnace as used in EXAMPLE 1):

1. 20 minutes purge at room temperature with 100% nitrogen at a flow rate of 80 SCFH.

2. Gas switched to 100% hydrogen at a flow rate of 10 SCFH.

3. Heat to 635° C. at a rate of 5° C./min.

4. Hold at 635° C. for 30 minutes.

5. Heat to 780° C. at a rate of 5° C./min.

6. Hold at 780° C. for 10 minutes.

7. Cool to 100° C. at a rate of 5° C./min (see below).

8. Gas switched to 100% nitrogen at a flow rate of 80 SCFH.

9. Purge with nitrogen for 20 minutes.

While a nominal cooling rate of 5° C./min was programmed into the furnace, the furnace did not have the means to cool itself down that quickly. The program instead allowed the furnace to cool as quickly as possible, with a 10° C. holdback from the programmed rate.

The hold temperatures were chosen according to the solidus and liquidus temperatures of the braze material (655° C. and 745° C., respectively, as reported by the supplier).

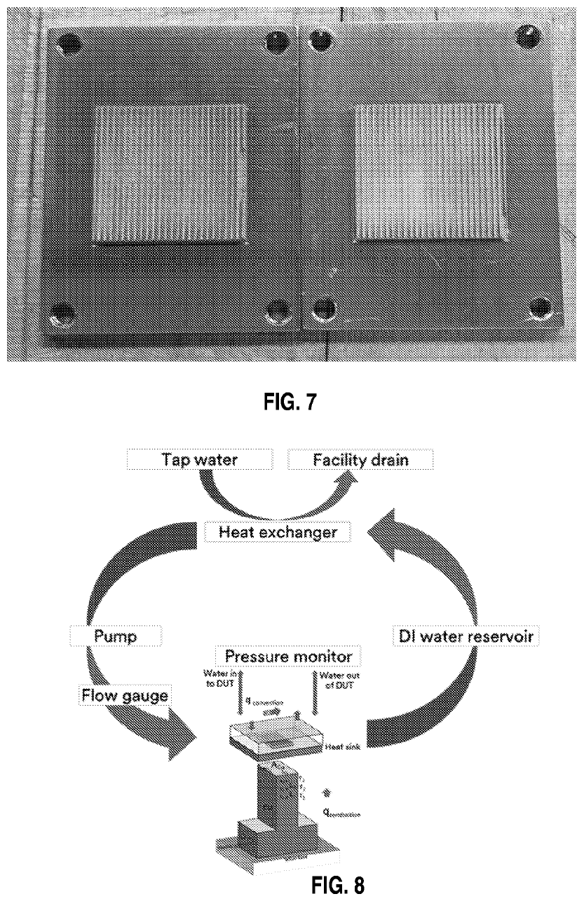

FIG. 7 shows the plate/braze/printed structure assembly after it had undergone the brazing heat treatment.

### Example 3: Printing of a Thinner Finned Structure Directly onto a Copper Plate

The steps from EXAMPLE 1 were repeated with the following two changes:
1. The width of the fins in the CAD model was reduced from 1 mm to 0.5 mm.
2. The length of the hold period at 900° C. during the second heat treatment was reduced from 10 hours to 5 hours.

### Thermal Performance

A custom benchtop setup was used to measure the thermal properties of the cold plates. The setup replicates the thermal environment of a processor, while allowing for more granular control and better repeatability across tests than a real processor.

The test setup comprised:
A reservoir of deionized water.
A water pump (Micropump 83472), with variable control by the input DC voltage (Micropump, Vancouver, Wash.).
A flow gauge (Micro-flo FTB324D, Omega, Norwalk, Conn.).
A thermocouple to measure the water temperature at the inlet to the device under test (DUT).
A heating system comprising:
   Copper heating pedestal with key dimensions the same as those of the processor it mimics.
   Heating rods inserted into copper heating pedestal.
   DUT attached to top of pedestal (micro-structured surface).
   Clear manifold attached to top of DUT.
   Pressure measurement (Setra 2301050PD2F11B) to monitor pressure drop across DUT (Setra, Boxborough, Mass.).
   Three thermocouples measuring copper pedestal temperature along its vertical length.
   Thermocouple attached to bottom side of DUT.
Data acquisition system (Keysight 34901A card with 34972A chassis) to monitor the thermocouple readings and water pressure readings (Keysight, Santa Rosa, Calif.).
Variable transformer to control AC power into heating rods (ISE, Inc., Cleveland, Ohio).

FIG. 8 is a schematic of custom benchtop testing apparatus.

Heating convection from the microstructures to the fluid was calculated from the difference in temperatures between the thermocouple mounted closest to the bottom of the cold plate and the inlet water temperature:

$$h = \frac{φ}{{T}_{plate} - {T}_{water}}$$

where the heating flux density φ was equal to power divided by cross-sectional area of the pedestal. Power through the pedestal was deduced from the temperature difference of the thermocouples embedded within the pedestal, such as x₁ and x₃ in FIG. 8. Tests consisted of collecting temperature, flow rate, and pressure data. Input parameters that were varied from test to test include the input power and the pump voltage (to modify flow rate).
Table 2 provides the thermal resistivities measured for the Examples described above.

TABLE 2
Thermal resistances of the cold plate structures
made in EXAMPLES 1-3 at a flow rate of 1 L/min.

| | Thermal resistance |
|---|---|
| Cold plate | (° C./W) |
| Example 1 - channel width: 800 um | 0.067 |
| Example 2, brazing foil - channel width: 500 um | 0.122 |
| Example 2, brazing paste - channel width: 500 um | 0.120 |
| Example 3 - channel width: 500 um | 0.050 |

### Baseline Comparison

Computational Fluid Dynamics (CFD) model was used to simulate thermal resistance of microchannel cold plate at different flow rate under the same condition as experimental setup. The Finite Volume Method (FVM) was employed to compute thermal and flow field in the computational domain.

The model was validated by fabricating and testing thermal performance of three different cold plates. Thermal resistance data was collected at flow rates between 200 and 1400 mLPM and compared to simulation results.

The first sample was a flat copper plate no microchannels.

Second and third samples had microchannels fabricated with Electro Discharge Machining (EDM) method to generate the microchannels, the channel width of which are 152 um and 203 um, respectively.

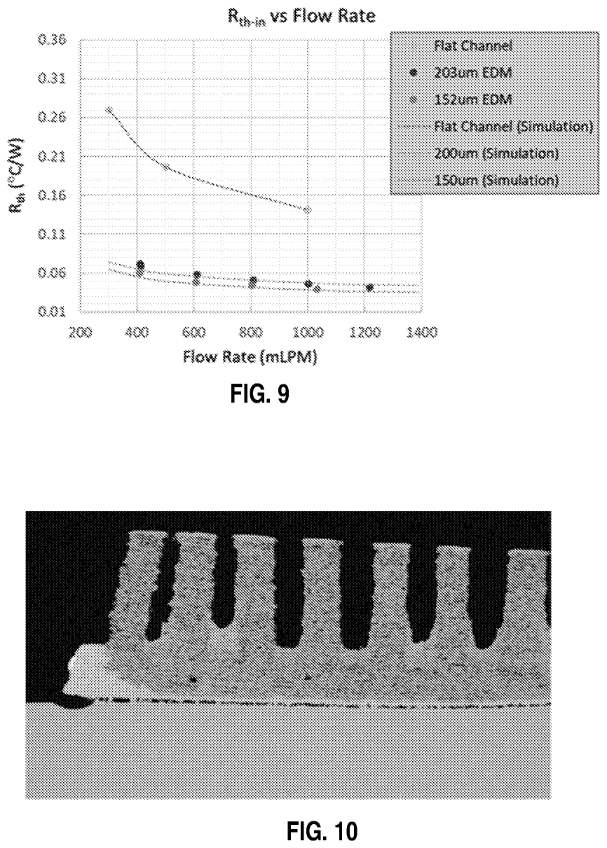

FIG. 9 compares simulated performance with experimentally determined values of thermal resistance for the three samples.

This computation demonstrates simulation predicting heat sink performance within 3% of experimentally measured thermal impedance at flow rate of 1000 mLPM. Thus, the simulation provided the effective means of performance prediction with high confidence.

Table 3 compares the performance of heat sink manufactured using the method of EXAMPLE 3 to predicted performance of machined-copper heat sinks with the same (EXAMPLE 4) and 2× smaller (EXAMPLE 5).

The thermal performance of the sample EXAMPLE 3 was superior (thermal resistance was ×2.4 smaller) than in a comparable machined-copper sample. Its thermal resistance was even significantly smaller than the resistance of a machined-copper heat sink with channel width of 250 μm. This was an unexpected result with the improvement achieved by using binder jetting to fabricate the heat sink channels.

TABLE 3
Thermal resistance performance comparison
at flow rate of 1000mLPM.

| | Thermal resistance |
|---|---|
| Cold plate | (° C./W) |
| EXAMPLE 3, with channel width | 0.050 |
| of 500 um (measurement) | |
| EXAMPLE 4, copper microchannel with | 0.120 |
| channel width of 500 um (simulation) | |
| EXAMPLE 5, copper microchannel with | 0.063 |
| channel width of 250 um (simulation) | |

FIG. 10 is a backscatter image for the finned structure made for EXAMPLE 2, showing horizontal lines indicating the presence of layers and a porous structure from 3D printing.

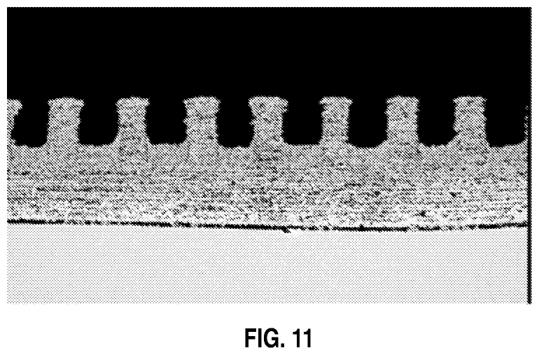

FIG. 11 is a backscatter image for the finned structure made for EXAMPLE 2, showing horizontal lines indicating the presence of layers and a porous structure from 3D printing.

1. A cold plate, comprising:
a metal base plate; and
a plurality of fins on the metal base plate, wherein the fins are porous and comprise an additively manufacturable material.

2. The cold plate of claim 1, wherein the metal base plate comprises copper.

3. The cold plate of claim 1, wherein the fins comprise a copper-silver alloy.

4. The cold plate of claim 1, wherein the fins comprise copper.

5. The cold plate of claim 1, wherein the fins comprise a copper-based alloy.

6. The cold plate of claim 1, wherein the fins are straight.

7. The cold plate of claim 1, wherein the fins are curved.

8. The cold plate of claim 1, wherein the fins have a width of approximately 600 microns−1 millimeter prior to heat treatment.

9. The cold plate of claim 1, wherein the fins have a spacing of approximately 500 microns prior to heat treatment.

10. The cold plate of claim 1, wherein the pores of the fins have diameters of approximately 5 microns-10 microns after heat treatment.

11. A cold plate cooling system, comprising:
a metal plate;
a cold plate on the metal plate, wherein the cold plate comprises:
a metal base plate; and
a plurality of fins on the metal base plate, wherein the fins are porous and comprise an additively manufacturable material; and
a manifold on the metal plate and over the cold plate, wherein the manifold includes at least one first port for receiving a coolant into the manifold and at least one second port for exiting the coolant from the manifold.

12. The system of claim 11, wherein the metal plate comprises copper.

13. The system of claim 11, wherein the metal base plate comprises copper.

14. The system of claim 11, wherein the fins comprise a copper-silver alloy.

15. The system of claim 11, wherein the fins comprise copper.

16. The system of claim 11, wherein the fins comprise a copper-based alloy.

17. The system of claim 11, wherein the fins are straight.

18. The system of claim 11, wherein the fins are curved.

19. The system of claim 11, wherein the fins have a width of approximately 600 microns−1 millimeter prior to heat treatment.

20. The system of claim 11, wherein the fins have a spacing of approximately 500 microns prior to heat treatment.

21. The system of claim 11, wherein the pores of the fins have diameters of approximately 5 microns-10 microns after heat treatment.

22. The system of claim 11, further comprising a thermal interface material on a side of the metal plate opposite the cold plate.

23-26. (canceled)
